(19) United States
(12) Patent Application Publication
(10) Pub. No.: US 2024/0198250 A1
(43) Pub. Date: Jun. 20, 2024

(54) VAPORIZER AND LIQUID MATERIAL VAPORIZING DEVICE

(71) Applicant: HORIBA STEC, Co., Ltd., Kyoto-shi (JP)

(72) Inventor: Keisuke NISHIWAKI, Kyoto-shi (JP)

(21) Appl. No.: 18/545,984

(22) Filed: Dec. 19, 2023

(30) Foreign Application Priority Data
Dec. 20, 2022 (JP) 2022-203318

(51) Int. Cl. B01B 1/00; B01F 23/232; B01F 25/4314; B01F 35/92

(52) U.S. Cl. CPC B01B 1/005; B01F 23/232; B01F 25/43141; B01F 35/92; B01F 2101/58

(57) ABSTRACT

A vaporizer includes a vaporization chamber in which a liquid material is heated and vaporized and a heat exchange element arranged in the vaporization chamber. The vaporization chamber has a groove in its inner surface. This helps improve vaporization performance of the liquid material and the vaporization of the liquid material at a high flow rate.

### INCORPORATION BY REFERENCE

This application is based upon and claims the benefit of priority from the corresponding Japanese Patent Application No. 2022-203318 filed on Dec. 20, 2022, the entire contents of which are incorporated herein by reference.

### BACKGROUND

The present invention relates to a vaporizer and a liquid material vaporizing device.

In a vaporizer of a DLI (direct liquid injection) type, a gas/liquid mixture in which a liquid material is mixed with a carrier gas is sprayed into a vaporization chamber through a nozzle to vaporize the liquid material. To completely vaporize the liquid material in the vaporization chamber, the vaporization chamber is heated by a heater.

In the vaporization chamber, a heat exchange element such as a static mixer may be inserted. The heat exchange element is inserted to increase the contact area with the liquid material to be vaporized, thereby to improve the heat exchanging efficiency of the liquid material and to improve the vaporization performance of the liquid material.

A resin-made static mixer just for stirring is disclosed, for example, in JP-A-2010-247348.

Due to a recent trend for an increased film deposition area in a semiconductor manufacturing process, it is desired to vaporize a liquid material at a high flow rate to feed it to a semiconductor manufacturing apparatus. To vaporize a liquid material at a high flow rate, it is necessary to further improve the heat exchanging efficiency of the liquid material in a vaporization chamber to further improve vaporization performance. In this respect, conventional vaporizers leave room for improvement.

### SUMMARY

The present invention is devised to solve the above problem and its object is to provide a vaporizer that can improve the vaporization performance of a liquid material to achieve high-rate vaporization of the liquid material, and to provide a liquid material vaporizing device incorporating such a vaporizer.

According to one aspect of what is disclosed herein, a vaporizer includes a vaporization chamber in which a liquid material is heated and vaporized and a heat exchange element arranged in the vaporization chamber. The vaporization chamber has a grove in its inner surface.

According to another aspect of what is disclosed herein, a vaporizer includes a vaporization chamber in which a liquid material is heated and vaporized and a heat exchange element arranged in the vaporization chamber. The heat exchange element is configured as a static mixer with a plurality of fins coupled together along the center axis, and the fins has an opening.

According to yet another aspect of what is disclosed herein, a liquid material vaporizing device includes the vaporizer described above and a liquid material feeding portion that feeds the vaporizer with a liquid material.

This and other objects of the present invention, and the specific benefits obtained according to the present invention, will become apparent from the description of embodiments which follows.

### BRIEF DESCRIPTION OF THE DRAWINGS

FIG. 1 is a sectional view schematically showing an outline of the structure of a liquid material vaporizing device according to one embodiment of the present invention.

FIG. 2 is a perspective view showing part of a static mixer as a heat exchange element provided in a vaporizer in the liquid material vaporizing device.

FIG. 3 is a plan view of the static mixer.

FIG. 4 is a diagram showing the static mixer as seen along its axis.

FIG. 5 is a perspective view of the vaporizer with the static mixer arranged in it as seen from the outlet side.

FIG. 6 is a diagram showing the vaporizer as seen along the center axis.

FIG. 7 is a perspective view showing part of another static mixer as the heat exchange element.

FIG. 8 is a diagram showing the another static mixer as seen along its axis.

### DETAILED DESCRIPTION

Illustrative embodiments of the present invention will be described below with reference to the accompanying drawings.

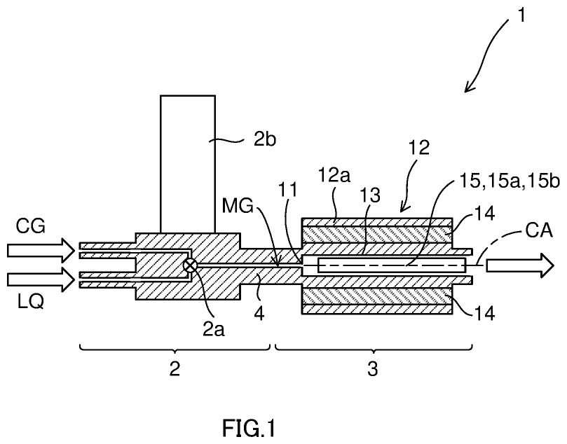

FIG. 1 is a sectional view schematically showing an outline of the structure of a liquid material vaporizing device 1 according to an embodiment. The liquid material vaporizing device 1 is provided in, for example, a semiconductor manufacturing apparatus (not shown). The liquid material vaporizing device 1 includes a liquid material feeding portion 2 and a vaporizer 3. Although the liquid material feeding portion 2 and the vaporizer 3 are connected together via a connecting portion 4, they may be connected together directly with no connecting portion 4.

The liquid material feeding portion 2 feeds a liquid material LQ to the vaporizer 3. Such a liquid material feeding portion 2 comprises, for example, a flow control valve (flow regulating valve). In particular, in the embodiment, the liquid material feeding portion 2 feeds the vaporizer 3 with a gas/liquid mixture MG in which the liquid material LQ is mixed with a carrier gas CG. The liquid material LQ mentioned above is a liquid material for a desired gas to be used in a semiconductor manufacturing process. As the carrier gas CG mentioned above, for example, an inert gas such as nitrogen or argon can be used.

The liquid material LQ and the carrier gas CG are mixed together in a gas-liquid mixing portion 2a. The gas-liquid mixing portion 2a is configured to have, for example, a valve seat member and a valve body member. The valve body member is driven by an actuator 2b to move into and out of contact with the valve seat member. As the valve body member moves into and out of contact with the valve seat member, the supply of the liquid material LQ that flows through the gap between the valve seat member and the valve body member is turned on and off. This makes it possible to switch whether to mix the liquid material LQ with the carrier gas CG. The actuator 2b is configured with, for example, a piezo stack composed of a plurality of piezoelectric elements stacked on each other, but it may be configured with a solenoid or the like.

The vaporizer 3 includes a nozzle 11 and a vaporizing portion 12. The vaporizing portion 12 is a cylindrical structure extending along a center axis CA and has a vaporization chamber 13 in it. In a cylindrical side wall portion 12a that forms the side wall of the vaporization chamber 13, a heater 14 that heats the vaporization chamber 13 is embedded.

The nozzle 11 is arranged at one end of the vaporizing portion 12 along the center axis CA and sprays the gas/liquid mixture MG fed from the liquid material feeding portion 2 into the vaporization chamber 13. The liquid material LQ contained in the sprayed gas/liquid mixture MG is heated in the vaporization chamber 13 to be vaporized. Thus, the vaporizer 3 includes the vaporization chamber 13 that heats and vaporizes the liquid material LQ. The gas vaporized in the vaporization chamber 13 is discharged from the other end (the outlet side) of the vaporization chamber 13 along the center axis CA toward the unillustrated semiconductor manufacturing apparatus.

The vaporizer 3 includes a heat exchange element 15. The heat exchange element 15 is inserted into the vaporization chamber 13 from, for example, the outlet side and is arranged in contact with the inner surface of the vaporization chamber 13 at a predetermined position. Instead, for example, before the nozzle 11 is fixed to the inlet of the vaporizing portion 12 by welding or the like, the heat exchange element 15 may be inserted into the vaporization chamber 13 from the inlet side, and then the nozzle 11 may be welded to the inlet of the vaporizing portion 12. Thus, there is no particular limitation on the insertion direction of the heat exchange element 15 during its placement in the vaporization chamber 13. The heat exchange element 15 is formed of, for example, a metal material with good thermal conductivity. Examples of such metal materials include SUS (stainless steel), copper, aluminum, and titanium.

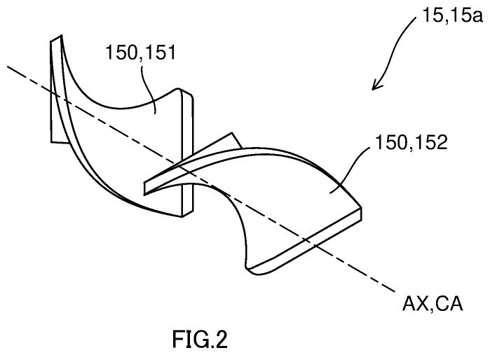

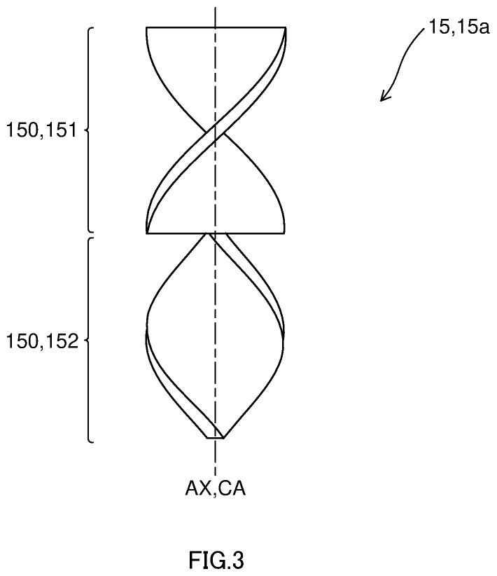

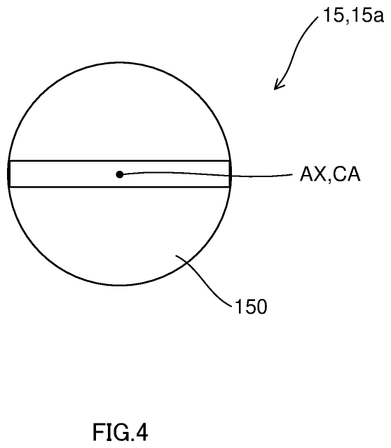

The heat exchange element 15 comprises, for example, a static mixer 15a. FIGS. 2 and 3 are a perspective view and a plan view, respectively, showing part of the static mixer 15a. FIG. 4 is a diagram of the static mixer 15a as seen along its axis AX. Here, with the static mixer 15a arranged in the vaporization chamber 13, the axis AX of the static mixer 15a coincides with the center axis CA of the vaporizing portion 12. Thus, in the vaporizer 3, the “axis AX” of the static mixer 15a can be read as the “center axis CA” as necessary.

The static mixer 15a as the heat exchange element 15 is configured with a plurality of fins 150 coupled together along the axis AX, that is, along the center axis CA. There is no particular limitation on the number of fins 150 so long as it is more than one. The plurality of fins 150 include a first fin 151 and a second fin 152. The first fin 151 is formed of a flat plate twisted counterclockwise as seen from one side along the center axis CA. That is, the first fin 151 is, as seen along the center axis CA, formed by twisting a flat plate in one direction along the circumferential direction about the center axis CA. The second fin 152 is formed of a flat plate twisted clockwise as seen from one side along the center axis CA. That is, the second fin 152 is, as seen along the center axis CA, formed by twisting a flat plate in a direction opposite to the above-mentioned one direction along the circumferential direction. The first and second fins 151 and 152 are positioned alternately along the center axis CA and are coupled together by welding or the like.

How the static mixer 15a is formed is not limited to how it is described to be formed above. For example, the static mixer 15a may be formed on a 3D printer capable of shaping using a metal material, or by cutting a columnar member such as a round or square columnar shape.

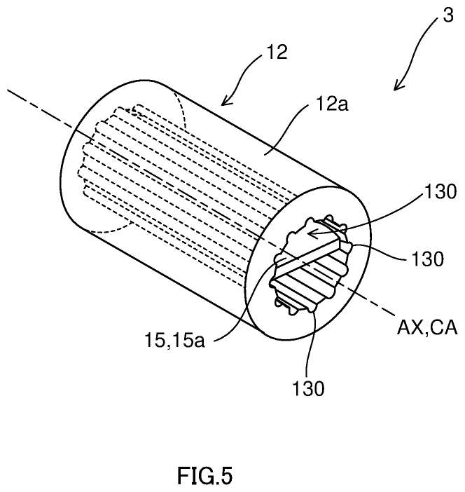

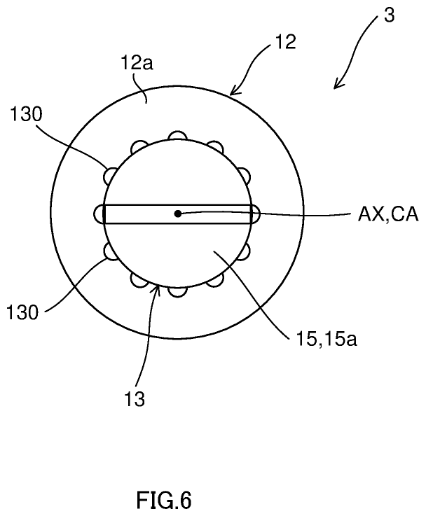

FIG. 5 is a perspective view of the vaporizer 3 with the static mixer 15a arranged in the vaporization chamber 13 as seen from the outlet side. FIG. 6 is a diagram showing the vaporizer 3 as seen along the center axis CA. The vaporization chamber 13 has grooves 130 in its inner surface. The grooves 130 are disposed in the inner surface of the vaporization chamber 13 along the center axis CA along which the vaporization chamber 13 extends. As shown in FIG. 6, the grooves 130 are arrayed in the inner surface of the vaporization chamber 13 at intervals in the circumferential direction as seen along the center axis CA. There is no particular limitation on the number of grooves 130; at least one groove 130 may be formed in the inner surface of the vaporization chamber 13.

Forming the grooves 130 in the inner surface of the vaporization chamber 13 as in the embodiment, compared to a configuration with no grooves 130, increases the surface area of the inner surface of the vaporization chamber 13. This increases the contact area of the liquid material LQ contained in the gas/liquid mixture MG introduced in the vaporization chamber 13 with the inner surface of the vaporization chamber 13. It is thus possible to improve the heat exchanging efficiency of the liquid material LQ in the vaporization chamber 13 and thus to improve the vaporization performance of the liquid material LQ. In addition, in the vaporization chamber 13, owing to the liquid material LQ making contact with both the heat exchange element 15 and the grooves 130 in the vaporization chamber 13, complex turbulences of a fluid are produced in the vaporization chamber 13. The fluid just mentioned contains the liquid material LQ before vaporization, the gas resulting from the liquid material LQ vaporizing, and the carrier gas CG. The turbulences described above further improve the heat exchanging efficiency of the liquid material LQ contained in the fluid and thus further improve the vaporization performance of the liquid material LQ. Thus, even if the liquid material LQ is led into the vaporization chamber 13 at a high flow rate, it is possible to vaporize the high-rate liquid material LQ and discharge it to the semiconductor manufacturing apparatus. That is, it is possible to improve the vaporization performance of the liquid material LQ and to achieve high-rate vaporization of the liquid material LQ, which is desired in recent years.

In particular, with the liquid material vaporizing device 1 configured such that the liquid material feeding portion 2 feeds the gas/liquid mixture MG to the vaporizer 3 and the liquid material LQ contained in the gas/liquid mixture MG is vaporized in the vaporizer 3, it is possible to achieve high-rate vaporization of the liquid material LQ.

From what has been described thus far, the grooves 130 formed in the inner surface of the vaporization chamber 13 can be understood to be a structure that can increase the surface area of the inner surface of the vaporization chamber 13, that can produce complex turbulences in the vaporization chamber 13 as the gas/liquid mixture MG (liquid material LQ) enters the groove 130, and that can improve heat exchanging efficiency. From FIG. 6, the groove 130 can also be understood to be a structure that is disposed, as seen along the center axis CA, outward of the static mixer 15a in the radial direction.

Since, in the vaporizer 3, the grooves 130 are disposed in the vaporization chamber 13 along the center axis CA, it is possible to achieve improved vaporization performance resulting from an increased contact area and complex turbulences as mentioned above across the entire vaporization chamber 13 along the center axis CA. Thus, it is possible to vaporize a high-rate liquid material reliably. In addition, with the configuration where the grooves 130 runs along the center axis CA, it is easy to form the grooves 130 in the inner surface of the vaporization chamber 13.

In the inner surface of the vaporization chamber 13, the grooves 130 may be formed in a spiral shape or about the center axis CA (in the circumferential direction). In that case, the vaporizing portion 12 can be manufactured, for example, as follows. The structure (vaporizing portion 12) including the vaporization chamber 13 is divided into two parts along a plane including the center axis CA and, after the grooves 130 in desired shapes are formed in them, the divided parts of the structure are bonded together. The groove 130 may be discontinuous.

As shown in FIG. 6, the grooves 130 are arrayed in the inner surface of the vaporization chamber 13 at intervals in the circumferential direction, and are disposed at a plurality of positions in the circumferential direction. This helps reliably increase the contact area of the liquid material with the inner surface of the vaporization chamber 13, and helps reliably produce complex turbulences of the fluid containing the liquid material.

The heat exchange element 15 is configured with the static mixer 15a having a plurality of fins 150 coupled together. With the fins 150, the liquid material LQ can be stirred in the vaporization chamber 13. This makes it possible to produce more complex turbulences in the vaporization chamber 13 and thereby improve the heat exchanging efficiency and hence the vaporization performance of the liquid material LQ.

The static mixer 15a includes the first and second fins 151 and 152 that are coupled with each other alternately along the center axis CA. In this structure, the first and second fins 151 and 152 repeatedly divide the flow path of the liquid material LQ (into paths on one and the other sides of the fin 150) and then join the divided flow paths in the vaporization chamber 13. It is thus possible to produce more complex turbulences in the vaporization chamber 13 reliably, and thus to improve vaporization performance.

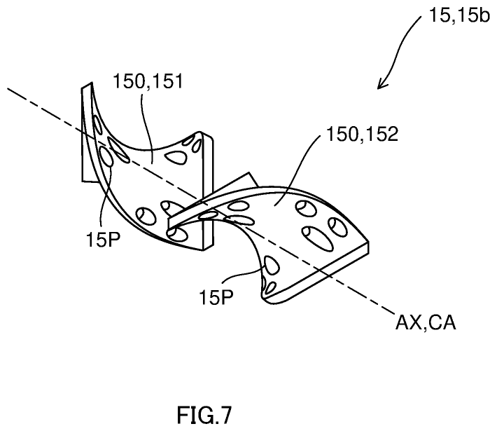

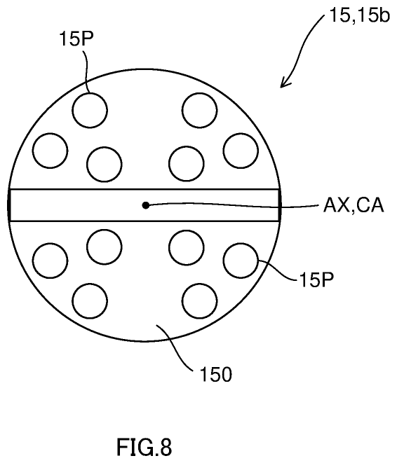

FIG. 7 is a perspective view showing part of another static mixer 15b. FIG. 8 is a diagram showing the static mixer 15b as seen along its axis AX. As the heat exchange element 15 arranged in the vaporization chamber 13 of the vaporizer 3 shown in FIG. 1, instead of the static mixer 15a, a static mixer 15b may be used.

As shown in FIGS. 7 and 8, the static mixer 15b has a structure similar to that of the static mixer 15a shown in FIG. 2 except that the first and second fins 151 and 152 each have at least one opening 15P formed in it. The opening 15P is formed as a hole that opens along the axis AX. Such a static mixer 15b can be manufactured by driving a cutting tool (such as a drill) through each fin 150 of the static mixer 15a shown in FIG. 2 and other diagrams along the axis AX so as to form a through hole that serves as the opening 15P.

The opening 15P may be formed as a cut with a partly open circumference instead of as a hole with a closed circumference. The opening 15P may be formed in only one of the first and second fins 151 and 152. For example, the first fin 151 with the opening 15P may be coupled with the second fin 152 with no opening 15P along the axis AX by welding or the like to form the static mixer 15b. The opening 15P may be a hole that penetrates the fin 150 in its thickness direction (a direction perpendicular to one or the other side of the fin 150).

As discussed above, at least one of the plurality of fins 150 that constitute the static mixer 15b has an opening 15P. By arranging such a static mixer 15b in the vaporization chamber 13, it is possible to create in the vaporization chamber 13 a flow path of the liquid material LQ that runs through the opening 15P in the fin 150 in addition to the flow path divided by the fin 150 into two (to one and the other sides of it) to run along the fin 150. Owing to the plurality of fins 150 repeatedly dividing those flow paths and then joining the divided flow paths, complex turbulences of a fluid can be produced in the vaporization chamber 13 more reliably. As a result, it is possible to further enhance the effect of the embodiment devised to improve vaporization performance.

The vaporizer 3 with the static mixer 15b shown in FIGS. 7 and 8 arranged in the vaporization chamber 13 can be defined as follows. The vaporizer 3 includes the vaporization chamber 13 that heats and vaporizes the liquid material LQ and the heat exchange element 15 arranged in the vaporization chamber 13. The heat exchange element 15 comprises the static mixer 15b with a plurality of fins 150 coupled together along the center axis CA. At least one of the plurality of fins 150 of the static mixer 15b has an opening 15P. With this configuration, it is possible to produce complex turbulences of a fluid in the vaporization chamber 13 more reliably, and thus to further enhance the effect of the embodiment devised to improves vaporization performance.

Even when the static mixer 15b is used as the heat exchange element 15, it is preferable that the grooves 130 be formed in the inner surface of the vaporization chamber 13, but they do not necessarily need to be formed. That is, when the static mixer 15b is used as the heat exchange element 15, even if no grooves 130 are formed in the inner surface of the vaporization chamber 13, it is possible to improve the vaporization performance of the liquid material LQ in the vaporization chamber 13 and to achieve the vaporization of the liquid material LQ at a high flow rate.

Although the embodiment deals with a liquid material vaporizing device 1 of an internal mixing type in which the liquid material LQ is mixed with the carrier gas CG in the liquid material feeding portion 2, the liquid material vaporizing device 1 may be of an external mixing type in which the liquid material LQ is mixed with the carrier gas CG outside the liquid material feeding portion 2. In the external mixing type, for example, the liquid material feeding portion 2 introduces the liquid material LQ into the vaporization chamber 13 via the nozzle 11, and introduces the carrier gas CG into the vaporization chamber 13 via another route. Also with such an external mixing type, it is equally possible, by applying the configuration of the vaporizer 3 of the embodiment, to improve the vaporization performance of the liquid material LQ and thereby achieve the vaporization of the material LQ at a high flow rate.

In the configuration in FIG. 1, the heat exchange element 15 may be configured with a filling material instead of the static mixer 15a. The filling material is configured to include a metallic granular material and filters arranged upstream and downstream of the granular material in the flow path. Here, the width of the grooves 130 in the inner surface of the vaporization chamber 13 is assumed to be smaller than the diameter of the granular material mentioned above so that the liquid material LQ contained in the gas/liquid mixture MG to be introduced in the vaporization chamber 13 is reliably brought into contact with the grooves 130 in the inner surface of the vaporization chamber 13. With the filling material, it is possible to achieve heat exchanging efficiency equivalent to that achieved with the static mixer 15a; thus, using the filling material instead of the static mixer 15a also helps improve the vaporization performance of the liquid material LQ and achieve the vaporization of the liquid material LQ at a high flow rate.

As described thus far, according to the present invention, it is possible to improve the vaporization performance of a liquid material and to achieve the vaporization of the liquid material at a high flow rate.

The description given above of an embodiment of the present invention is in no way meant to limit the scope of the present invention; the present invention can be implemented with any modifications made without departing from the spirit of the present invention.

The present invention is applicable to, for example, vaporizers as are provided in a stage preceding a semiconductor manufacturing apparatus.

What is claimed is:

1. A vaporizer comprising:
a vaporization chamber in which a liquid material is heated and vaporized; and
a heat exchange element arranged in the vaporization chamber,
wherein
the vaporization chamber has a groove in an inner surface thereof.

2. The vaporizer according to claim 1,
wherein,
the groove in the inner surface of the vaporization chamber is disposed along a center axis along which the vaporization chamber extends.

3. The vaporizer according to claim 2,
wherein,
the groove in the inner surface of the vaporization chamber comprises grooves arrayed at intervals in a circumferential direction as seen along the center axis.

4. The vaporizer according to claim 3,
wherein,
the heat exchange element is configured as a static mixer with a plurality of fins coupled together along the center axis.

5. The vaporizer according to claim 4,
wherein,
the plurality of fins include
a first fin twisted in one direction along a circumferential direction as seen along the center axis, and
a second fin twisted in an opposite direction along the circumferential direction as seen along the center axis, and
the first and second fins are coupled together alternately along the center axis.

6. The vaporizer according to claim 5,
wherein
at least one of the plurality of fins has an opening.

7. The vaporizer according to claim 2,
wherein,
the heat exchange element is configured as a static mixer with a plurality of fins coupled together along the center axis.

8. The vaporizer according to claim 7,
wherein,
the plurality of fins include
a first fin twisted in one direction along a circumferential direction as seen along the center axis and
a second fin twisted in an opposite direction along the circumferential direction as seen along the center axis, and
the first and second fins are coupled together alternately along the center axis.

9. The vaporizer according to claim 8,
wherein
at least one of the plurality of fins has an opening.

10. The vaporizer according to claim 7,
wherein
at least one of the plurality of fins has an opening.

11. The vaporizer according to claim 4,
wherein
at least one of the plurality of fins has an opening.

12. A liquid material vaporizing device comprising:
the vaporizer according to claim 1; and
a liquid material feeding portion that feeds the vaporizer with a liquid material.

13. The liquid material vaporizing device according to claim 12,
wherein
the liquid material feeding portion feeds the vaporizer with a gas/liquid mixture in which the liquid material is mixed with a carrier gas.

14. A vaporizer comprising:
a vaporization chamber in which a liquid material is heated and vaporized; and
a heat exchange element arranged in the vaporization chamber,
wherein
the heat exchange element is configured as a static mixer with a plurality of fins coupled together along the center axis, and
at least one of the plurality of fins has an opening.

15. A liquid material vaporizing device comprising:
the vaporizer according to claim 14; and
a liquid material feeding portion that feeds the vaporizer with a liquid material.

16. The liquid material vaporizing device according to claim 15,
wherein
the liquid material feeding portion feeds the vaporizer with a gas/liquid mixture in which the liquid material is mixed with a carrier gas.
